(19) United States
(12) Patent Application Publication
(10) Pub. No.: US 2026/0327786 A1
(43) Pub. Date: Oct. 22, 2026

(54) SUBSTRATE PROCESSING METHOD AND SUBSTRATE PROCESSING APPARATUS

(71) Applicant: Tokyo Electron Limited, Tokyo (JP)

(72) Inventor: Miyako KANEKO, Yamanashi (JP)

(21) Appl. No.: 19/468,242

(22) Filed: Feb. 3, 2026

Related U.S. Application Data
(63) Continuation of application No. PCT/JP2024/025267, filed on Jul. 12, 2024.

(30) Foreign Application Priority Data
Aug. 17, 2023 (JP) 2023-132928

(51) Int. Cl. C23C 16/02; C23C 16/26; C23C 16/455; C23C 16/56

(52) U.S. Cl. CPC C23C 16/02; C23C 16/26; C23C 16/45557; C23C 16/56

(57) ABSTRACT

A substrate processing method is provided, including: preparing a substrate having a foundation film; hydrophobizing a surface of the substrate; selectively hydrophilizing a periphery of the substrate; forming a carbon-containing film having a film stress of 1 GPa or greater on the substrate by setting a processing pressure to a first pressure; and selectively removing the carbon-containing film on the hydrophilized periphery of the substrate by setting the processing pressure to a second pressure higher than the first pressure.

### CROSS-REFERENCE TO RELATED APPLICATIONS

This application is a continuation application of International Application No. PCT/JP2024/025267, filed on Jul. 12, 2024, and designating the U.S., which is based upon and claims priority to Japanese Patent Application No. 2023-132928, filed on Aug. 17, 2023, the entire contents of which are incorporated herein by reference.

### BACKGROUND

### TECHNICAL FIELD

The present disclosure relates to a substrate processing method and a substrate processing apparatus.

### BACKGROUND ART

For example, Japanese Patent Application Laid-Open Publication No. 2007-157828 proposes removing an SiO₂ film on a bevel of a substrate by spinning a stage on which the substrate is mounted, supplying an active gas into a processing chamber, and irradiating the bevel of the substrate with laser light.

For example, Japanese Patent Application Laid-Open Publication No. 2010-520646 proposes supplying a cleaning gas into a processing chamber, supplying an RF power to a bottom edge electrode, and grounding a top edge electrode, thereby forming a cleaning plasma near the bevel and the edge of a substrate, and cleaning the bevel and the edge of the substrate.

For example, Japanese Patent Application Laid-Open Publication No. 2014-45171 proposes forming a masking film on the periphery of a substrate, then forming a hard mask on the surface of the substrate, and after this, removing the hard mask on the periphery of the substrate, and then removing the masking film on the periphery of the substrate.

### SUMMARY

According to one embodiment of the present disclosure, a substrate processing method is proposed, including: preparing a substrate having a foundation film; performing hydrophobization treatment in which a surface of the substrate is hydrophobized; performing hydrophilization treatment in which a periphery of the substrate is selectively hydrophilized; forming a carbon-containing film having a film stress of 1 GPa or greater on the substrate by setting a processing pressure to a first pressure; and selectively removing the carbon-containing film on the hydrophilized periphery of the substrate by setting the processing pressure to a second pressure higher than the first pressure.

### BRIEF DESCRIPTION OF THE DRAWINGS

FIG. 1 is an example of a schematic cross-sectional view of a substrate processed by a substrate processing method;

FIG. 2 is a diagram showing an example of a result of film peeling of a carbon-containing film on a surface of an Si substrate;

FIG. 3 is a diagram showing an example of a result of film peeling of a carbon-containing film on a surface of a TiN substrate;

FIG. 4 is a flowchart showing an example of a substrate processing method according to a first embodiment;

FIG. 5 is a diagram for explaining the substrate processing method of FIG. 4;

FIG. 6 is a flowchart showing an example of a substrate processing method according to a second embodiment;

FIG. 7 is a diagram for explaining the substrate processing method of FIG. 6;

FIG. 8 is a flowchart showing an example of a substrate processing method according to a third embodiment;

FIG. 9 is a diagram for explaining the substrate processing method of FIG. 8;

FIG. 10 is a flowchart illustrating an example of a substrate processing method according to a fourth embodiment;

FIG. 11 is a diagram for explaining the substrate processing method of FIG. 10;

FIG. 12 is a view illustrating an example of a substrate processing system;

FIG. 13 is a schematic cross-sectional view showing an example of a substrate processing apparatus for applying a hydrofluoric acid treatment, an ammonia-hydrogen peroxide treatment, or a pure water rinsing treatment;

FIG. 14 is a configuration view illustrating an example of a substrate processing apparatus for applying a hydrofluoric acid treatment or a pure water rinsing treatment;

FIG. 15 is a schematic cross-sectional view illustrating an example of a substrate processing apparatus for applying a hydrophobization treatment with an Si-containing gas; and

FIG. 16 is a schematic cross-sectional view illustrating an example of a substrate processing apparatus for applying a carbon-containing film formation process or a series of treatments of a substrate processing method.

### DETAILED DESCRIPTION OF THE INVENTION

Hereinafter, embodiments for carrying out the present disclosure will be described with reference to the drawings. In the drawings, the same components are denoted by the same reference numerals, and redundant descriptions may be omitted.

### Technology for Inhibiting Film Peeling

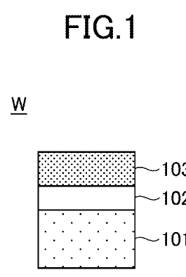

For example, as shown in FIG. 1, a carbon-containing film 103 (for example, DLC: Diamond Like Carbon) is formed on a substrate W having a first layer 101 and a second layer 102. The first layer 101 is, for example, a Magnetic Tunnel Junction (MTJ) element. The second layer 102 may be, for example, an Si-containing film (Si, SiO₂, SiN, and the like). The second layer 102 may be, for example, a metal-containing film (TiN, W, Co, and the like).

When the second layer 102 is TiN, the second layer 102 and the carbon-containing film 103 can be used as a hard mask of the first layer 101 (for example, an MTJ element). In this case, the thickness of the TiN film (the second layer 102) is preferably 20 nm to 100 nm. The thickness of the carbon-containing film 103 (carbon-containing film) is preferably 20 nm to 100 nm. Thus, a thin hard mask having a high etching resistance can be formed.

The carbon-containing film 103 has a high compressive stress, and thus has a poor adhesiveness to the second layer 102. Therefore, the carbon-containing film 103 formed on the second layer 102 might peel.

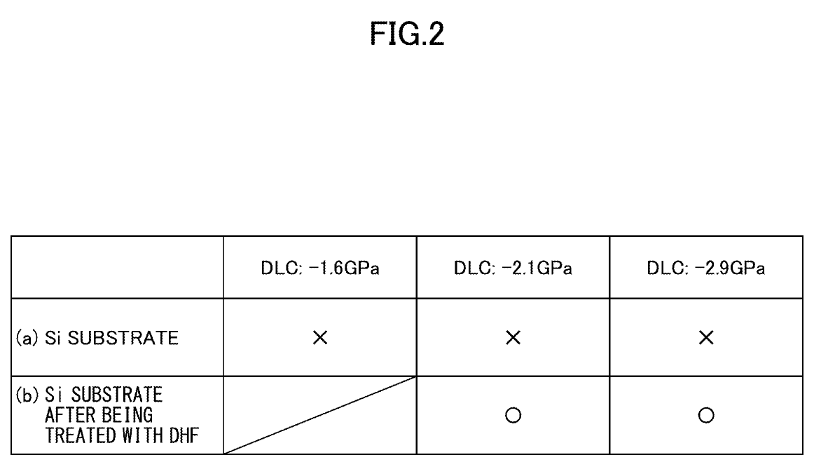

FIG. 2 is a diagram showing states when DLC films were formed as a carbon-containing film on a substrate surface. Here, DLC films having compressive stresses of -1.6 GPa, -2.1 GPa, and -2.9 GPa were formed on (a) a brand-new Si substrate and (b) an Si substrate hydrophobized with hydrofluoric acid (DHF). In the diagram, “○” indicates that the film did not peel, and “×” indicates that the film peeled. When the film stress has a negative value, a film having a compressive stress is formed. When the film stress has a positive value, a film having a tensile stress is formed.

As shown in FIG. 2, on (a) the brand-new Si substrate, film peeling was confirmed from all of the DLC films having compressive stresses of -1.6 GPa, -2.1 GPa, and -2.9 GPa. This is because the surface of the brand-new Si substrate is a hydrophilic surface having a multitude of Si-OH formed by termination with OH groups, and thus has a poor adhesiveness to allow the films to peel.

As shown in FIG. 2, on (b) the Si substrate hydrophobized by DHF, the DLC film having a compressive stress of -2.1 GPa did not peel. In addition, on the Si substrate hydrophobized by DHF, the DLC film having a compressive stress of -2.9 GPa did not peel, either. This is because the surface of the Si substrate hydrophobized by DHF is a hydrophobic surface having a multitude of Si-H formed by termination with H groups, and thus has a good adhesiveness that can inhibit film peeling.

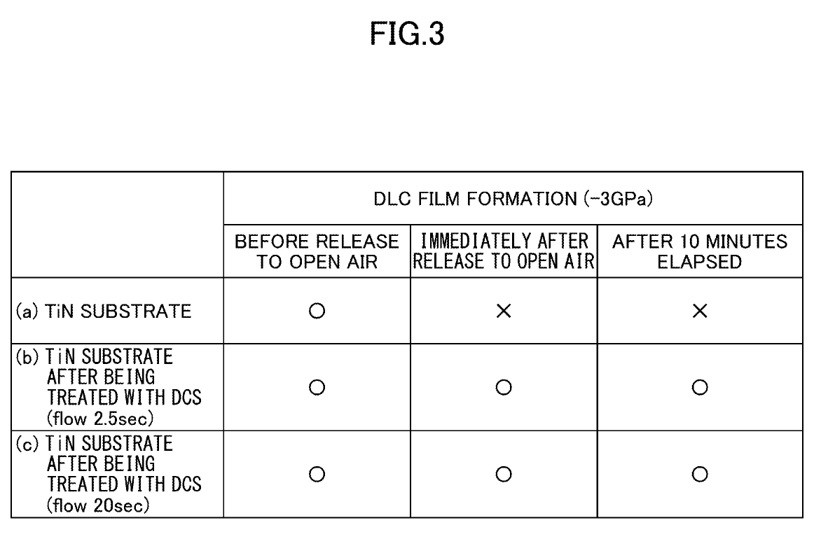

Next, the state of film peeling when a carbon-containing film was formed on the metal-containing film was confirmed. FIG. 3 shows states when a DLC film was formed as a carbon-containing film on the surface of a metal-containing film, which was a TiN metal-containing film. Here, DLC films having a compressive stress of -3.0 GPa were formed on (a) a TiN substrate, (b) a TiN substrate subjected to hydrophobization treatment by exposing the TiN substrate to dichlorosilane (DCS: SiH₂Cl₂) gas for 2.5 seconds, and (c) a TiN substrate subjected to hydrophobization treatment by exposing the TiN substrate to dichlorosilane (DCS: SiH₂Cl₂) gas for 20 seconds. After the DLC films were formed, the states of the films were observed before being released to the open air, immediately after being released to the open air, and when 10 minutes elapsed since being released to the open air. “○” indicates that the film did not peel, and “×” indicates that the film peeled.

As shown in FIG. 3, on (a) the TiN substrate, film peeling was not confirmed before the film was released to the open air. On the other hand, film peeling was confirmed immediately after the film was released to the open air, and when 10 minutes elapsed after the film was released to the open air. This is because the TiN film is a hydrophilic film, whereas the DLC film is an organic film mainly composed of C=C bonds, C-C bonds, and C-H bonds, and is a hydrophobic film. Therefore, at the junction between the TiN film and the DLC film, a hydrophilic film and a hydrophobic film form a junction, and have a poor adhesiveness and a low adhesive force. Therefore, when the DLC film having a film stress of 1 GPa or greater was formed on the TiN film, the DLC film underwent film peeling due to the film stress of the DLC film itself.

As shown in FIG. 3, on (b) the TiN substrate subjected to hydrophobization treatment by exposing the TiN substrate to dichlorosilane (DCS: SiH₂Cl₂) gas for 2.5 seconds, and (c) the TiN substrate subjected to hydrophobization treatment by exposing the TiN substrate to dichlorosilane (DCS: SiH₂Cl₂) gas for 20 seconds, film peeling did not occur in any of the cases where the films were in the state before being released to the open air, in the state immediately after being released to the open air, and in the state when 10 minutes elapsed since being released to the open air. This is because hydrophobic groups (SiHx) having an Si atom and an H atom physically adsorbed to and/or chemically bonded with the surface of the TiN film, which resulted in a junction of a hydrophobic surface and a hydrophobic film being formed at the junction between the TiN film and the DLC film, between which adhesiveness was good and a large adhesive force occurred. Therefore, even though the DLC film having a film stress of 1 GPa or greater was formed on the TiN film, film peeling of the DLC film could be inhibited.

From the above, it was revealed that, when the second layer 102 is an Si-containing film or a TiN film, film peeling of the carbon-containing film 103 could be inhibited when the surface of the second layer 102 was hydrophobic, and that film peeling of the carbon-containing film 103 occurred when the surface of the second layer 102 was hydrophilic.

The carbon-containing film 103 that became adherent to the bevel of a substrate and the front and back surfaces of the edge of the substrate (hereinafter also referred to as a “periphery of the substrate”) might become particles by being rubbed against other parts, such as a conveying device and the like, during substrate conveying. Therefore, there is a post-etching step of removing the carbon-containing film 103 that became adherent to the periphery of the substrate. In the post-etching step of the present embodiment, only the carbon-containing film 103 on the periphery of the substrate is removed after the carbon-containing film 103 is formed. Specifically, using the above-described substrate surface state control (film peeling control), a treatment for imparting a hydrophobic surface to the center of a substrate and imparting a hydrophilic surface to the periphery of the substrate is performed. Thereafter, a carbon- containing film is formed on the substrate at a first pressure, and only the carbon-containing film formed on the periphery of the substrate is selectively removed by being processed at a second pressure higher than the first pressure.

In the substrate processing method according to the first to fourth embodiments described below, the carbon-containing film 103 on the periphery of the substrate is selectively removed by utilizing the surface treatment on the second layer 102. Hereinafter, the substrate processing method according to the respective embodiments will be described in order. Hereinafter, the numerical values of the film stress are expressed as absolute values in both of a case of forming a carbon-containing film 103 having a compressive stress and a case of forming a carbon-containing film 103 having a tensile stress. The film stress of the carbon-containing film 103 may be in a compressive direction or a tensile direction. That is, the carbon-containing film 103 (DLC film) having a film stress of 1 GPa or higher by absolute value will be formed.

### First Embodiment

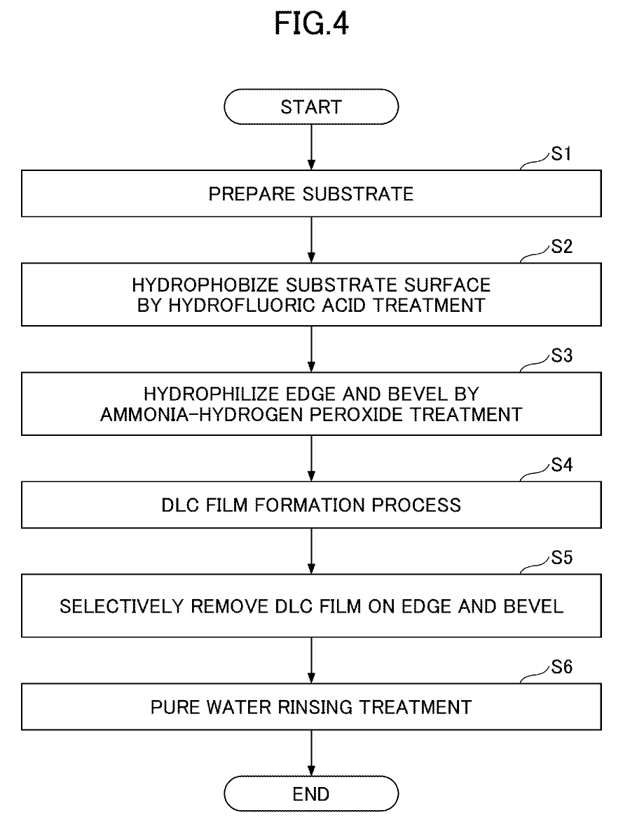

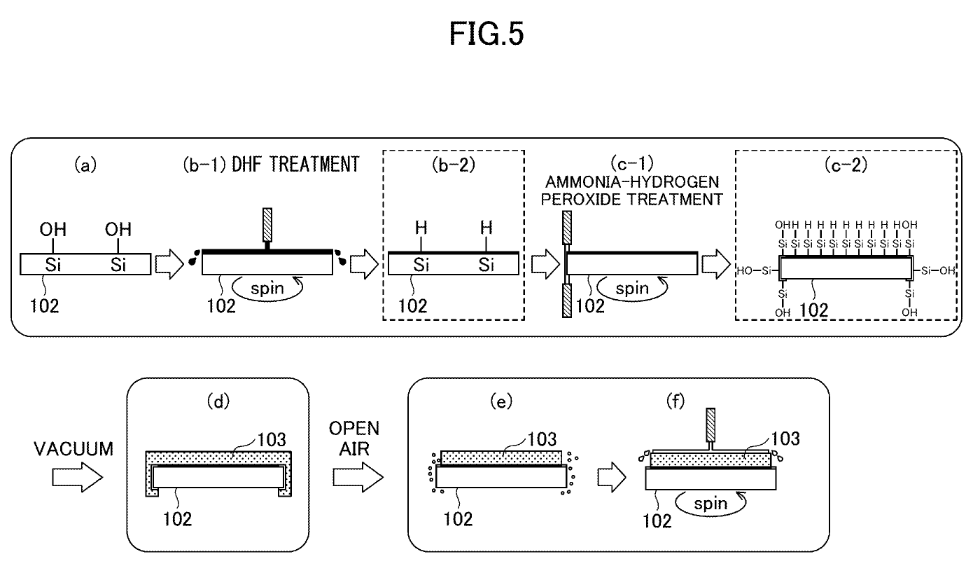

First, the substrate processing method according to the first embodiment will be described with reference to FIGS. 4 and 5. FIG. 4 is a flowchart showing an example of the substrate processing method according to the first embodiment. FIG. 5 is a diagram for explaining the substrate processing method of FIG. 4.

In the substrate processing method according to the first embodiment, first, in step S1, a substrate W having a foundation film is prepared on a stage in a processing vessel of a substrate processing apparatus described later. Here, the substrate W to be prepared has a first layer 101 and a second layer 102 (FIG. 1). In the present embodiment, the second layer 102 as the foundation film is an Si-containing film. That is, the surface of the prepared substrate W is the surface of the second layer 102 and may be any one of Si, SiO₂, or SiN.

FIG. 5 shows the prepared substrate W at (a). For example, the surface of the second layer 102 of the substrate W is a hydrophilized surface terminated with OH groups forming Si-OH.

Next, in step S2, the surface of the substrate W is hydrophobized by exposing the substrate to a first treatment solution. In the present embodiment, the first treatment solution is hydrofluoric acid (DHF), and as shown at (b-1) of FIG. 5, in the DHF treatment, hydrofluoric acid (DHF) is supplied from a nozzle disposed in the center of the stage while spinning the stage on which the substrate W is mounted, to apply surface treatment to the entirety of the surface of the second layer 102. Note that the first treatment solution is not limited to hydrofluoric acid (DHF), and may also contain at least one of BHF, TMSDMA, HMDS, or a silane coupling agent. For example, when the surface of the second layer 102 of the substrate W is Si, at least one of hydrofluoric acid or BHF may be included for hydrophobization. Further, for example, when the surface of the second layer 102 of the substrate W is SiO2 or SiN, at least one of TMSDMA, HMDS, or a silane coupling agent may be included for hydrophobization. Thus, as shown at (b-2) of FIG. 5, the surface of the second layer 102 of the substrate W is terminated with H groups to form Si-H, and is hydrophobized. Thus, the surface of the second layer 102 of the substrate W is modified.

Next, in step S3, the surface of the substrate W is hydrophilized by selectively exposing the periphery of the substrate to a second treatment solution different from the first treatment solution. In the present embodiment, as shown at (c-1) of FIG. 5, ammonia-hydrogen peroxide is supplied to the periphery of the substrate from a nozzle disposed at the periphery of the substrate while spinning the stage, to treat the periphery of the substrate (the bevel of the substrate and the front and back surface of the edge of the substrate) with the ammonia-hydrogen peroxide chemical solution (SC1). Note that the second treatment solution may contain at least one of ammonia-hydrogen peroxide, hydrochloric acid-hydrogen peroxide (a mixture of hydrochloric acid and hydrogen peroxide), ozone water (O₃), water, hydrogen peroxide (H₂O₂), sulfuric acid-hydrogen peroxide, or an ammonium peroxodisulfate aqueous solution.

In this way, as shown at (c-2) of FIG. 5, the periphery of the substrate is selectively hydrophilized. Thus, the surface of the periphery of the substrate can be terminated with OH groups to form Si-OH, and can be hydrophilized. Other than the periphery, the remaining part of the substrate, that is, the center surface of the substrate, remains being Si-H and hydrophobic. Thus, a surface having hydrophobicity and a surface having hydrophilicity can be selectively formed on the substrate.

Next, in step S4, the pressure in the processing vessel (processing pressure) is controlled to the first pressure, and a carbon-containing film 103 having a film stress of 1 GPa or greater is formed on the substrate W. The first to fourth embodiments show cases where a DLC film (DLC film 103) is formed as the carbon-containing film 103. For example, the first pressure may be 0.13 Pa to 13.3 Pa. The step of forming the DLC film 103 includes exposing the substrate W to a plasma formed from a third processing gas containing a carbon-containing gas. The carbon-containing gas contains at least one of a gas containing carbon and hydrogen, a gas containing carbon and fluorine, a gas containing carbon and oxygen, or a gas containing carbon and metal. The carbon-containing gas may be carbon-hydrogen gas. The third processing gas may further contain an inert gas. The inert gas contains at least one of argon (Ar) gas, helium (He) gas, nitrogen (N₂) gas, xenon (Xe) gas, or krypton (Kr) gas. In this way, as shown at (d) in FIG. 5, a DLC film 103 having a high film stress (1 GPa or greater) is formed.

Next, in step S5, the processing pressure is controlled to the second pressure higher than the first pressure to selectively remove the DLC film 103 on the hydrophilized periphery of the substrate. The second pressure is, for example, the atmospheric pressure. The second pressure may be, for example, equal to or higher than the maximum value (13.3 Pa) of the first pressure. The second pressure may be, for example, the atmospheric pressure, or may be in a subatmospheric pressure range of 10,000 Pa or higher and 100,000 Pa or lower in a processing vessel environment in which moisture and oxygen exist. In this case, the moisture (humidity) may be 10% to 100% and the oxygen concentration may be 1% to 20%.

According to this, for example, due to the substrate W being put in an atmospheric pressure environment, only the DLC film 103 on the hydrophilized periphery of the substrate starts to peel. The DLC film 103 on the hydrophobized surface of the substrate does not peel. Thus, as shown at (e) in FIG. 5, as only the DLC film on the periphery of the substrate comes to have a poor adhesiveness and peels, the DLC film on the periphery of the substrate can be selectively removed.

Next, in step S6, the substrate W is cleaned. A chemical solution is supplied from a nozzle, and the periphery of the substrate is cleaned by pure water (De-Ionized Water: DIW) rinsing treatment. The step of cleaning the substrate W includes exposing the substrate W to a third treatment solution. The third treatment solution may be pure water (DIW). Thus, as shown at (f) in FIG. 5, the peeled DLC film 103 can be rinsed away with pure water and removed. The pure water rinsing may be ultrasonic pure water rinsing. Instead of pure water rinsing, dilute ammonia-hydrogen peroxide may be used to remove the peeled DLC film.

According to the substrate processing method according to the first embodiment, it is possible to selectively remove the DLC film 103 on the hydrophilized periphery of the substrate by utilizing the phenomenon in which the DLC film 103 on the hydrophilized periphery of the substrate peels and the DLC film 103 on the hydrophobized surface of the substrate does not peel at a desired pressure.

### Second Embodiment

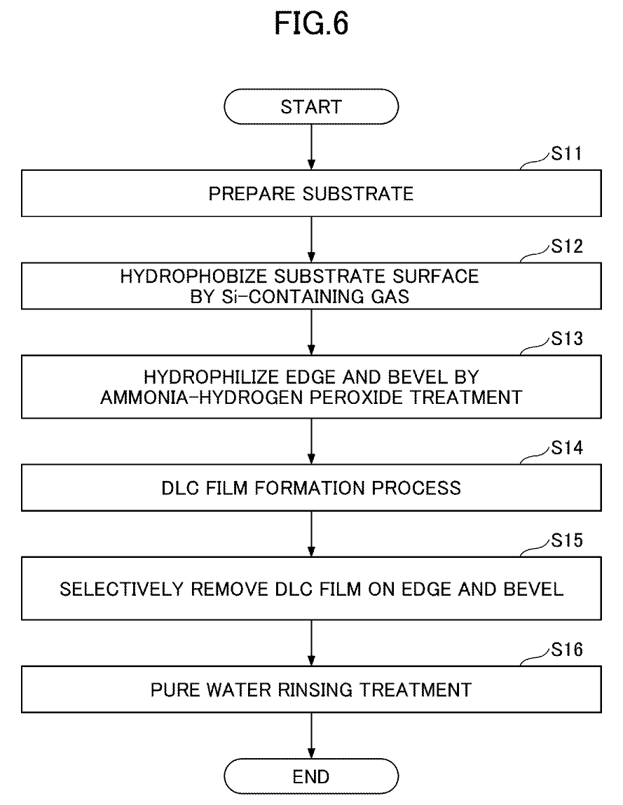

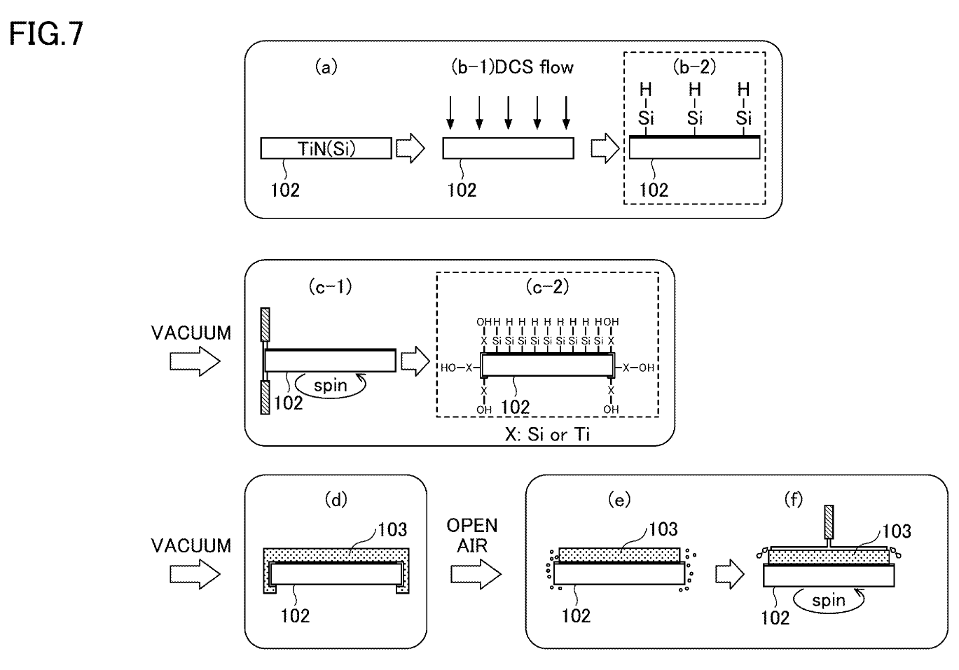

Next, a substrate processing method according to the second embodiment will be described with reference to FIGS. 6 and 7. FIG. 6 is a flowchart showing an example of the substrate processing method according to the second embodiment. FIG. 7 is a diagram for explaining the substrate processing method of FIG. 6.

In the substrate processing method according to the second embodiment, first, in step S11, a substrate having a foundation film is prepared. The substrate W prepared here has a first layer 101 and a second layer 102 (FIG. 1). In the present embodiment, the second layer 102 as the foundation film is a TiN film or an Si-containing film. That is, the substrate surface of the prepared substrate W is the surface of the second layer 102, and may be any one of Si, SiO₂, SiN, or TiN. When the second layer 102 is an Si-containing film, the surface of the second layer 102 of the prepared substrate W is a hydrophilized surface terminated with OH groups forming Si-OH. When the second layer 102 is a TiN film, the surface of the second layer 102 of the prepared substrate W is a hydrophilized surface terminated with OH groups forming Ti-OH, or is TiN without being terminated with OH groups as shown at (a) in FIG. 7. In this case, the surface of TiN is hydrophilic.

When the second layer 102 is TiN, the surface remains hydrophilic even by being treated with hydrofluoric acid (DHF). Therefore, in step S12, the surface of the substrate W is hydrophobized by exposing the substrate W to a first processing gas. When the second layer 102 is an Si-containing film, the surface of the substrate W can be hydrophobized by exposing the substrate to the first processing gas or the first treatment solution.

The first processing gas is an Si-containing gas containing an Si-H bond. The Si-H bond contains at least one of silane (SiH₄), disilane (Si₂H₆), trisilane (Si₃H₈), high-order silane, dichlorosilane (DCS: SiH₂Cl₂), trichlorosilane (SiHCl₃), or an organosilicon compound.

For example, as shown at (b-1) in FIG. 7, when the second layer 102 is TiN, the second layer 102 is exposed to dichlorosilane gas (DCS), which is an example of the Si-containing gas. Thus, as shown at (b-2) in FIG. 7, on the surface of the second layer 102 of the substrate W, hydrophobic groups containing Si-H bonds physically adsorb to and/or chemically bond with the TiN film. That is, Si and/or Si-H physically adsorbs to the surface of the TiN film. Thus, the hydrophilic surface of the TiN film is modified to a hydrophobic surface. Alternatively, Ti in the TiN film and Si-H chemically bond with each other to form Ti-Si-H. In other words, the terminal group of the surface is modified to (- Si-H).

Next, in step S13, the periphery of the substrate is treated with ammonia-hydrogen peroxide (SC1). As shown at (c-1) in FIG. 7, while spinning the stage, ammonia-hydrogen peroxide is supplied to the periphery of the substrate from a nozzle disposed at the periphery of the substrate. As a result, as shown at (c-2) of FIG. 7, the surface of the periphery of the substrate is terminated with OH groups to form Ti-Si-OH or Si-OH or Ti-OH, and can be hydrophilized. Other than the periphery of the substrate, the remaining part of the substrate, that is, the center surface of the substrate, remains being Ti-Si-H or Si-H and hydrophobic. Thus, a hydrophobic surface and a hydrophilic surface can be selectively formed on the substrate.

Next, in step S14, the pressure in the processing vessel (processing pressure) is controlled to the first pressure, and the DLC film 103 having a film stress of 1 GPa or greater is formed on the substrate W. For example, the first pressure may be 0.13 Pa to 13.3 Pa. Thus, as shown at (d) in FIG. 7, the DLC film 103 having a high film stress (1 GPa or greater) is formed.

Next, in step S15, the processing pressure is controlled to the second pressure higher than the first pressure, and the DLC film 103 on the hydrophilized periphery of the substrate is selectively removed. For example, the substrate W is exposed to the atmospheric pressure. As a result, as shown at (e) in FIG. 7, only the DLC film 103 on the periphery of the substrate having the hydrophilic substrate surface comes to have a poor adhesiveness and peels. Therefore, the DLC film 103 on the periphery of the substrate can be selectively removed.

Next, in step S16, a chemical solution is supplied from a nozzle, to clean the periphery of the substrate by pure water (DIW) rinsing treatment. Thus, as shown at (f) in FIG. 7, the peeled DLC film can be removed.

### Third Embodiment

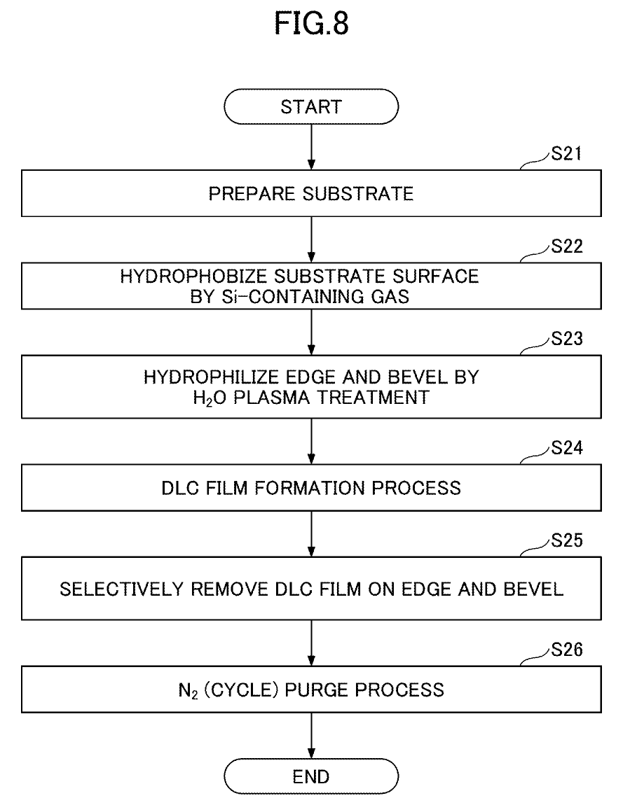

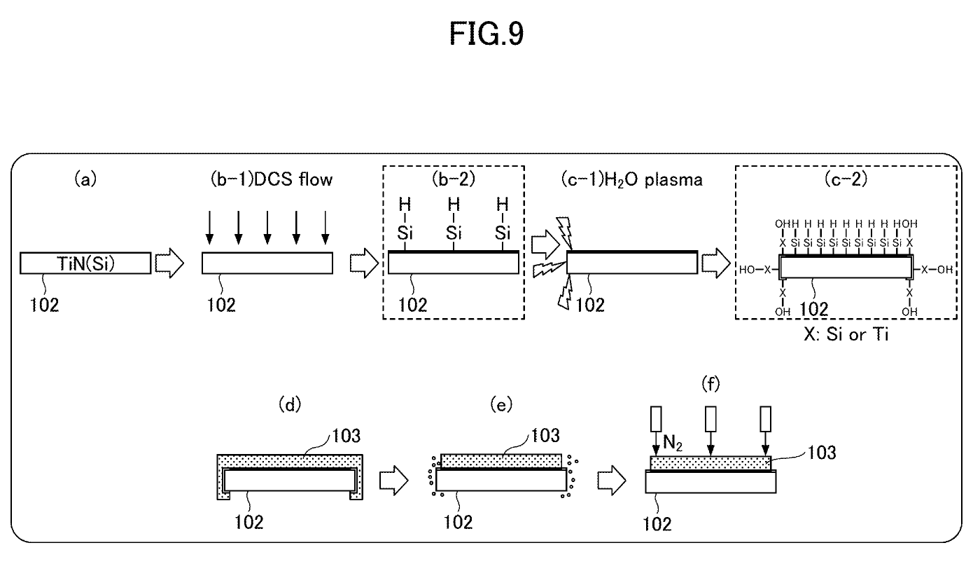

Next, a substrate processing method according to the third embodiment will be described with reference to FIGS. 8 and 9. FIG. 8 is a flowchart showing an example of the substrate processing method according to the third embodiment. FIG. 9 is a diagram for explaining the substrate processing method of FIG. 8.

In the substrate processing method according to the third embodiment, first, in step S21, a substrate having a foundation film is prepared. Here, the substrate W prepared has a first layer 101 and a second layer 102 (FIG. 1). In the present embodiment, the second layer 102 as the foundation film is an Si-containing film or a TiN film.

Next, in step S22, the surface of the substrate W is hydrophobized by exposing the substrate W to the first processing gas. For example, as shown at (b-1) in FIG. 9, the second layer 102 is exposed to dichlorosilane gas (DCS), which is an example of the Si-containing gas. On the surface of the second layer 102 of the substrate W, hydrophobic groups containing Si-H bonds physically adsorb to and/or chemically bond with the surface of the TiN film. That is, Si and/or Si-H physically adsorbs to the surface of the TiN film. Thus, the hydrophilic surface of the TiN film is modified to a hydrophobic surface. Alternatively, Ti in the TiN film and Si-H chemically bond with each other to form Ti-Si-H. In other words, the terminal group of the surface is modified to (-Si-H).

Then, in step S23, the periphery of the substrate is selectively exposed to a plasma formed from a second processing gas different from the first processing gas. The second processing gas contains at least one of water (H₂O), hydrogen peroxide (H₂O₂), or ozone water (O₃). In the example at (c-1) in FIG. 9, an H₂O plasma composed of water (vapor) is formed at the periphery of the substrate.

Thus, the periphery of the substrate is selectively hydrophilized, and as shown at (c-2) in FIG. 9, the surface of the periphery of the substrate is terminated with OH groups to form Ti-Si-OH, or Si-OH, or Ti-OH, and can be hydrophilized. Other than the periphery of the substrate, the remaining part of the substrate, i.e., the center surface of the substrate, remains being Ti-Si-H or Si-H, and hydrophobic. Thus, a hydrophobic surface and a hydrophilic surface can be selectively formed on the substrate.

Next, in step S24, the processing pressure in the processing vessel is controlled to the first pressure, and the DLC film 103 having a film stress of 1 GPa or greater is formed on the substrate W. Thus, as shown at (d) in FIG. 9, the DLC film 103 having a high film stress (1 GPa or greater) is formed.

Next, in step S25, the processing pressure is controlled to the second pressure higher than the first pressure, to selectively remove the DLC film 103 on the hydrophilized periphery of the substrate. For example, the substrate W is exposed to the atmospheric pressure. As a result, as shown at (e) in FIG. 9, only the DLC film 103 on the periphery of the substrate comes to have a poor adhesiveness and peels. Thus, the DLC film 103 on the periphery of the substrate can be selectively removed.

Next, in step S26, the substrate W is cleaned by exposing the substrate W to a fourth processing gas. For example, as an example of the fourth processing gas, N₂ gas is supplied into the processing vessel as a purge gas, to eject the peeled DLC to outside the processing vessel. For example, in step S26, a step of supplying N₂ gas into the processing vessel to purge the peeled DLC film 103 and a step of vacuuming the interior of the processing vessel by a gas exhaust, such as a vacuum pump and the like, may be repeated a set number of times.

Thus, as shown at (f) in FIG. 9, the peeled DLC film can be removed. It is preferable that the peeled DLC film is removed by a filter installed in a gas exhaust pipe before being sucked into a gas exhaust, such as a vacuum pump and the like.

The hydrophobizing step (S22), the hydrophilizing step (S23), the

carbon-containing film forming step (S24), the carbon-containing film selective removal step (S25), and the substrate cleaning step (S26) in FIG. 8 can be performed in the same processing vessel of a substrate processing apparatus 700 described later. Thus, the throughput can be improved and productivity can be improved.

### Fourth Embodiment

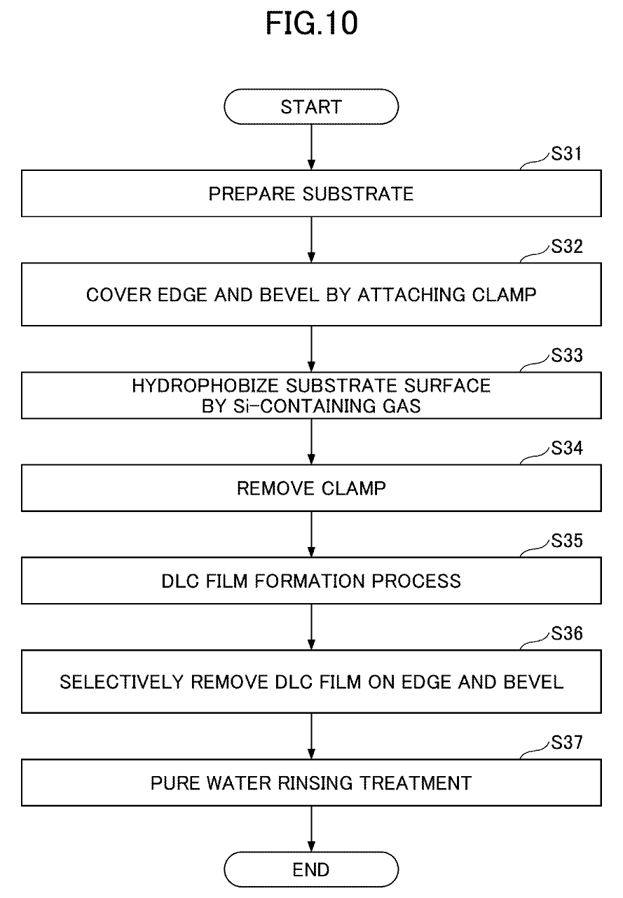

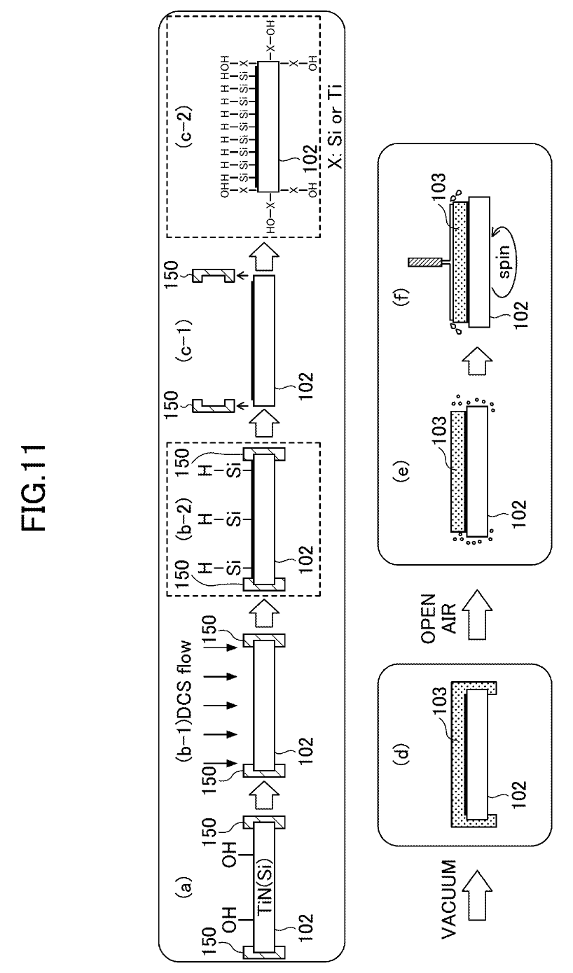

Next, a substrate processing method according to the fourth embodiment will be described with reference to FIGS. 10 and 11. FIG. 10 is a flowchart showing an example of the substrate processing method according to the fourth embodiment. FIG. 11 is a diagram for explaining the substrate processing method shown in FIG. 10.

In the substrate processing method according to the fourth embodiment, first, in step S31, a substrate having a foundation film is prepared. The substrate W prepared here has a first layer 101 and a second layer 102 (FIG. 1). After being prepared on the stage, the surface of the substrate W is hydrophilized using the same method as in the other embodiments. However, a substrate W having a hydrophilized surface may be prepared. In the present embodiment, the second layer 102 as the foundation film is an Si-containing film or a TiN film, and the surface of the substrate W has hydrophilicity.

Next, in step S32, as shown at (a) in FIG. 11, a clamp 150 for covering the periphery of the substrate is attached to the periphery of the substrate. The clamp 150 is an example of a fixture. Then, in step S33, as shown at (b-1) in FIG. 11, the surface of the substrate W is hydrophobized. The same method as in other embodiments can be used for making the surface of the substrate W hydrophobic. For example, in the hydrophobizing method by exposure to dichlorosilane gas (DCS), the periphery of the substrate is not exposed to DCS due to the clamp 150. As a result, as shown at (b-2) in FIG. 11, the surface of the substrate W other than the periphery of the substrate covered with the clamp 150 is hydrophobized.

Next, in step S34, as shown at (c-1) in FIG. 11, the clamp 150 is removed from the periphery of the substrate. Here, as shown at (c-2) in FIG. 11, the periphery of the substrate that has been covered with the clamp 150 is hydrophilic, and the remaining part of the surface of the substrate W is hydrophobized.

Next, in step S35, the pressure in the processing vessel (processing pressure) is controlled to the first pressure, and the DLC film 103 having a film stress of 1 GPa or greater is formed on the substrate W. Thus, as shown at (d) in FIG. 11, the DLC film 103 having a high film stress (1 GPa or greater) is formed.

Next, in step S36, the processing pressure is controlled to the second pressure higher than the first pressure, and the DLC film 103 on the hydrophilized (hydrophilized) periphery of the substrate is selectively removed. For example, the substrate W is exposed to the atmospheric pressure. As a result, as shown at (e) in FIG. 11, only the DLC film 103 on the periphery of the substrate comes to have a poor adhesiveness and peels. Thus, the DLC film 103 on the periphery of the substrate can be selectively removed.

Next, in step S37, the periphery of the substrate is cleaned by a pure water (DIW) rinsing treatment. As a result, as shown at (f) in FIG. 11, the peeled DLC film can be removed.

In the first to fourth embodiments, the second layer 102 may be a metal film, metal oxide, or metal nitride. The metal film, the metal contained in the metal oxide, and the metal contained in the metal nitride may be any one of Ti, Ru, Mo, Mg, W, Co, Fe, or Cu.

### Substrate Processing System

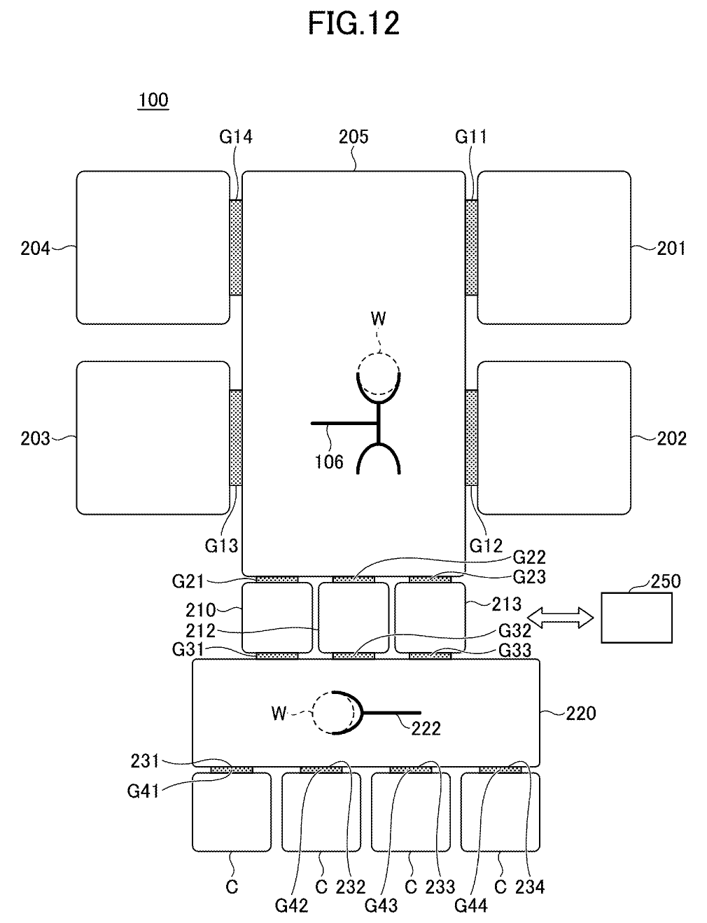

A processing system 100 used in the substrate processing method according to the first to fourth embodiments will be described with reference to FIG. 12. FIG. 12 is a view showing an example of a processing system 100 according to an embodiment.

The processing system 100 includes substrate processing apparatuses 201 to 204, a vacuum conveying chamber 205, load lock chambers 210, 212, and 213, an open-air conveying chamber 220, load ports 231 to 234, and a controller 250.

The substrate processing apparatuses 201 to 204 are connected to the vacuum conveying chamber 205 via gate valves G11 to G14, respectively. The interiors of the substrate processing apparatuses 201 to 204 are depressurized to a predetermined vacuum atmosphere, and a desired processing is performed on the substrate W in the interiors. The substrate processing apparatuses 201, 202, 203, and 204 are realized by any one of substrate processing apparatuses 400, 500, 600, or 700 described later.

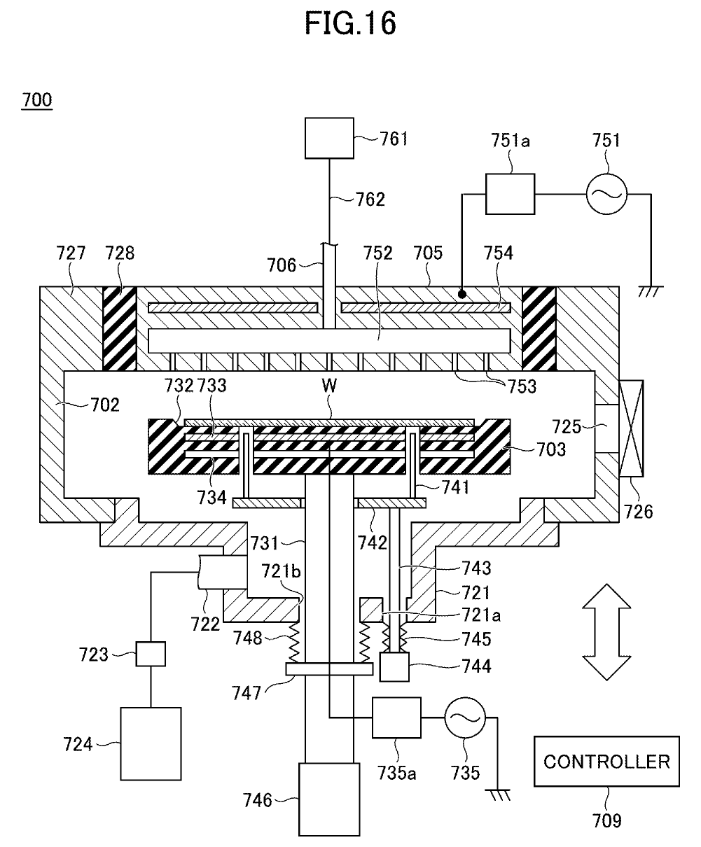

The substrate processing apparatus 201 is a substrate processing apparatus (film formation apparatus) for forming a metal-containing film as the second layer 102 of the substrate W. The metal-containing film is, for example, a TiN film. The substrate processing apparatus 201 is realized by the substrate processing apparatus 700 described later. An example of the substrate processing apparatus 201 will be described later with reference to FIG. 16.

Specifically, the substrate processing apparatus 201 forms a TiN film on the substrate W by an Atomic Layer Deposition (ALD) method by a Ti-containing gas (for example, TiCl₄ gas) and a reaction gas (nitriding gas, such as ammonia gas or N₂ gas) being alternately supplied into a processing vessel. Although the substrate processing apparatus 201 is described as a film formation apparatus for forming a TiN film (metal-containing film) on the substrate W by the ALD method, this is non-limiting. For example, the substrate processing apparatus 201 may be a film formation apparatus for forming a metal-containing film on the substrate W by a Chemical Vapor Deposition (CVD) method. The substrate processing apparatus 201 may be a film formation apparatus for forming a metal-containing film on the substrate W by a Physical Vapor Deposition (PVD) method.

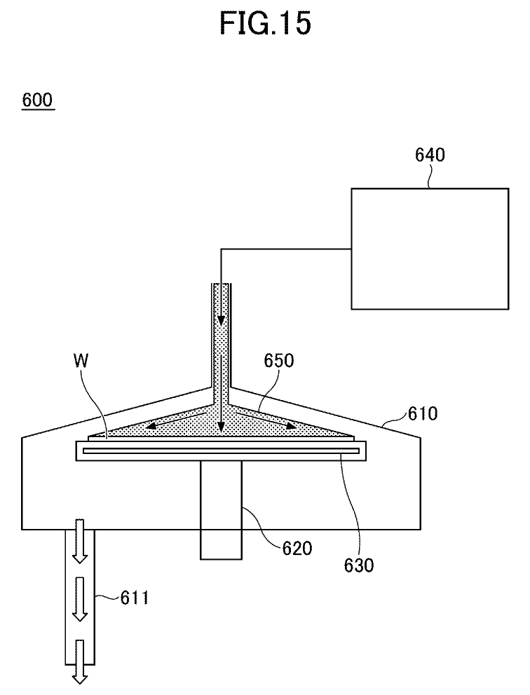

The substrate processing apparatus 202 performs steps S12 (FIG. 6), S22 (FIG. 8), and S33 (FIG. 10) to modify the surface of the second layer 102 formed on the substrate W with the Si-containing gas. Thus, the substrate processing apparatus hydrophobizes the surface of the substrate W. The substrate processing apparatus 202 is realized by the substrate processing apparatus 600 described later. An example of the substrate processing apparatus 202 will be described later with reference to FIG. 15.

The substrate processing apparatus 203 is a substrate processing apparatus (film formation apparatus) for forming a DLC film 103 (carbon-containing film) on the second layer 102 of the substrate W. The substrate processing apparatus 203 is realized by the substrate processing apparatus 700 described later. An example of the substrate processing apparatus 203 will be described later with reference to FIG. 16.

The substrate processing apparatus 204 may be a substrate processing apparatus that performs the same processing process as any of the substrate processing apparatuses 201 to 203 or a substrate processing apparatus (for example, an annealing apparatus, an etching apparatus, and the like) that performs a processing process different from any of the substrate processing apparatuses 201 to 203. The process for forming the second layer 102 on the substrate W and the process for modifying the surface of the second layer 102 formed on the substrate W with the Si-containing gas may be performed by the same substrate processing apparatus.

The vacuum conveying chamber 205 is depressurized to a predetermined vacuum atmosphere. The vacuum conveying chamber 205 is an example of a conveyor for conveying the substrate W. The vacuum conveying chamber 205 is provided with a conveying mechanism 106 capable of conveying the substrate W in a depressurized state. The conveying mechanism 106 conveys the substrate W to the substrate processing apparatuses 201 to 204 and to the load lock chambers 210, 212, and 213.

The load lock chambers 210, 212, and 213 are connected to the vacuum conveying chamber 205 via gate valves G21 to G23, respectively, and are connected to the open-air conveying chamber 220 via gate valves G31 to G33, respectively. The load lock chambers 210, 212, and 213 can be switched between the open-air atmosphere and a vacuum atmosphere.

In the open-air conveying chamber 220, an open-air atmosphere is formed, and, for example, a downflow of clean air is formed. An aligner (not shown) for aligning the substrate W is provided in the open-air conveying chamber 220. The open-air conveying chamber 220 is provided with a conveying mechanism 222. The conveying mechanism 222 conveys the substrate W to the load lock chambers 210, 212, 213, to carriers C at load ports 231 to 234 described later, and to the aligner.

The load ports 231 to 234 are provided on a wall surface of the open-air conveying chamber 220. A carrier C containing the substrate W or an empty carrier C is attached to the load ports 231 to 234 via gate valves G41 to G44. For example, a Front Opening Unified Pod (FOUP) can be used as the carrier C.

The controller 250 controls each part of the processing system 100. For example, the controller 250 controls the operations of the substrate processing apparatuses 201 to 204, the operations of the conveying mechanism 106 and 222, opening and closing of the gate valves G11 to G14, G21 to G23, G31 to G33, and G41 to G44, switching of the atmosphere in the load lock chambers 210, 212, and 213, and the like.

### Substrate Processing Apparatus 400

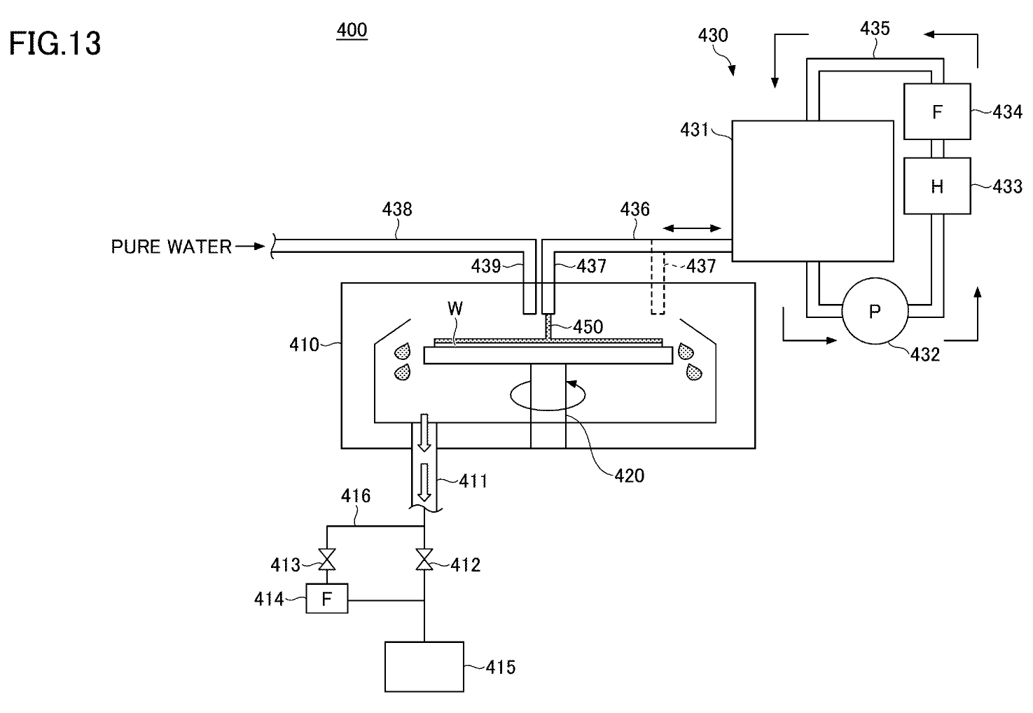

A configuration example of the substrate processing apparatus 400 used for the hydrofluoric acid (DHF) treatment (S2 (FIG. 4)), the ammonia-hydrogen peroxide treatment (S3 (FIG. 4), and S13 (FIG. 6)), or pure water (DIW) rinsing treatment (S6 (FIG. 4), S16 (FIG. 6), and S37 (FIG. 10)) will be described with reference to FIG. 13. FIG. 13 is a schematic cross-sectional view showing an example of the substrate processing apparatus 400 for performing the hydrofluoric acid treatment, the ammonia-hydrogen peroxide treatment, and the pure water rinsing treatment.

The substrate processing apparatus 400 includes a processing chamber 410, a stage 420 that can spin while having the substrate W mounted thereon, and a chemical supply 430. The chemical supply 430 includes a chemical tank 431, a pump 432, a heater 433, a filter 434, a circulation path 435, and a supply path 436. The circulation path 435 is formed to circulate from the chemical tank 431, to the pump 432, to the heater 433, and to the filter 434. Arrows indicate the circulation direction of a chemical 450. By circulating the chemical, it is possible to heat the chemical 450 in the chemical tank 431 to a predetermined temperature. The chemical 450 in the chemical tank 431 is supplied to the surface of the substrate in the processing chamber 410 through the supply path 436. By spinning of the stage 420, the chemical 450 flows in a direction toward the outer periphery of the substrate W and is drained from a draining path 411. The substrate W is dried by stopping the supply of the chemical 450 from the chemical supply 430 into the processing chamber 410 and spinning the stage 420 on which the substrate W is mounted.

In the hydrofluoric acid (DHF) treatment, the chemical 450 (hydrofluoric acid) in the chemical tank 431 is supplied from a nozzle 437 through the supply path 436, and the stage 420 is spun to supply the chemical to the entire surface of the substrate W. Thus, the surface of the substrate can be hydrophobized.

In the ammonia-hydrogen peroxide treatment, after the nozzle 437 is moved to the edge of the substrate W, the chemical 450 (ammonia-hydrogen peroxide) in the chemical tank 431 is supplied from the nozzle 437 through the supply path 436. The stage 420 is spun to supply the ammonia-hydrogen peroxide to the edge of the substrate W. Thus, the surface of the substrate can be hydrophilized.

In the pure water (DIW) rinsing treatment, the chemical supply 430 may be omitted. Pure water is supplied from a nozzle 439 through a utility line 438. Thus, the substrate W can be cleaned. The nozzle 439 is movable in the horizontal direction.

When draining the pure water (chemical 450) through the draining path 411 in the pure water rinsing treatment, a bypass line 416 is provided on the draining path 411 in order to prevent a peeled DLC film 103 from flowing directly into a gas exhaust 415.

In the hydrofluoric acid treatment and the ammonia-hydrogen peroxide treatment, a valve 413 on the bypass line 416 is closed, and a valve 412 is opened, in order for the chemical 450 to be directly drained through the draining path 411 by the exhaust device 415. In the pure water rinsing treatment, the valve 413 on the bypass line 416 is opened, and the valve 412 is closed, to cause the pure water to flow from the draining path 411 to the bypass line 416. Thus, the pure water is passed through a filter 414 provided on the bypass line 416, for the DLC film 103 contained in the pure water to be removed by the filter 414, and then drained by the gas exhaust 415. In this way, the gas exhaust 415 can be protected.

### Substrate Processing Apparatus 500

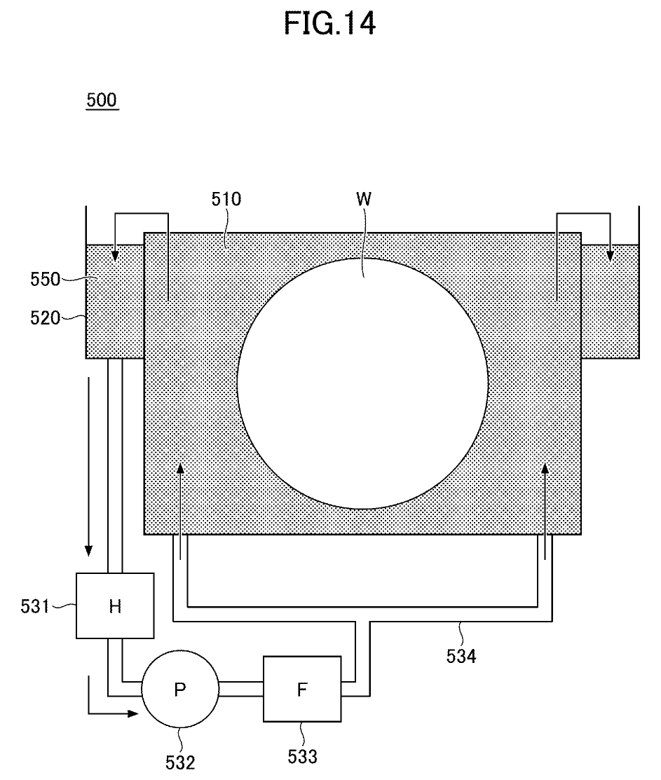

A batch-type substrate processing apparatus 500 shown in FIG. 14 may be used for the hydrofluoric acid (DHF) treatment or the pure water (DIW) rinsing treatment. Further, in a case of applying the ammonia-hydrogen peroxide treatment to the entire surface of a substrate W, the substrate processing apparatus 500 may be used for the ammonia-hydrogen peroxide treatment. FIG. 14 is a configuration diagram showing an example of the substrate processing apparatus 500 for applying the hydrofluoric acid treatment, the ammonia-hydrogen peroxide treatment (in a case of treating the entire surface of the substrate W), and the pure water rinsing treatment.

The substrate processing apparatus 500 includes an inner tank 510 for housing the substrate W, an outer tank 520, a heater 531, a pump 532, a filter 533, and a flow path 534. A chemical 550 (hydrofluoric acid and ammonia-hydrogen peroxide) or pure water is stored in the inner tank 510 and the outer tank 520. The chemical 550 or pure water drained from the inner tank 510 flows into the outer tank 520. The chemical 550 in the outer tank 520 passes the heater 531, the pump 532, and the filter 533 through the flow path 534, and is supplied into the inner tank 510 by being heated to a predetermined temperature. The arrows indicate the circulation direction of the chemical.

### Substrate Processing Apparatus 600

A configuration example of the substrate processing apparatus 600 used for hydrophobization treatment (S12 (FIG. 6), S22 (FIG. 8), and S33 (FIG. 10)) of a substrate surface with dichlorosilane gas (DCS) will be described with reference to FIG. 15. FIG. 15 is a schematic cross-sectional view showing an example of the substrate processing apparatus 600 for applying the hydrophobization treatment with the Si-containing gas. DCS and HMDS are examples of the Si-containing gas. Hydrophobization using DCS is a thermal process for blowing a gas without forming a plasma.

The substrate processing apparatus 600 includes a processing chamber 610, a stage 620 on which a substrate W is mounted, a heater 630 provided in the stage 620 for heating the stage 620 and the substrate W, and a gas supply 640. The gas supply 640 includes a vaporizer and vaporizes a chemical. A vaporized chemical 650 is the Si-containing gas. The vaporized chemical 650 is supplied into the processing chamber 610. The vaporized chemical 650 after being used for treatment is exhausted through a draining path 611.

For example, the substrate surface hydrophobized by exposing the substrate W to the Si-containing gas in step S22 (FIG. 8) is then subjected to the hydrophilization treatment on the periphery of the substrate by H₂O plasma treatment in step S23 (FIG. 8) by the substrate processing apparatus 700 (FIG. 16), which will be described next. Then, in step S24 (FIG. 8), the substrate processing apparatus 700 forms a carbon-containing film (DLC film 103) having a film stress of 1 GPa or greater.

### Substrate Processing Apparatus 700

A configuration example of the substrate processing apparatus 700 used for the process of forming a carbon-containing film (DLC film 103) (S4 (FIG. 4), S14 (FIG. 6), S24 (FIG. 8), and S35 (FIG. 10)) and for H₂O plasma treatment (step S23 (FIG. 8)) will be described with reference to FIG. 16. FIG. 16 is a schematic cross-sectional view showing an example of the substrate processing apparatus 700 for applying the carbon-containing film formation process or the series of treatments of the substrate processing method. The substrate processing apparatus 700 is a plasma processing apparatus.

The substrate processing apparatus 700 is an apparatus for forming a carbon-containing film (for example, a DLC film 103) on a substrate W by a Chemical Vapor Deposition (CVD) method in a processing vessel 702 at reduced pressure.

The substrate processing apparatus 700 includes a substantially cylindrical airtight processing vessel 702. A gas exhaust chamber 721 is provided in the center of the bottom wall of the processing vessel 702. The gas exhaust chamber 721 has, for example, a substantially cylindrical shape projecting downward. A gas exhaust path 722 is connected to the gas exhaust chamber 721, for example, on a side surface of the gas exhaust chamber 721. A gas exhaust 724 is connected to the gas exhaust path 722 via a pressure regulator 723. The pressure regulator 723 includes a pressure regulating valve, such as a butterfly valve and the like. The gas exhaust path 722 is configured to allow the interior of the processing vessel 702 to be depressurized by the gas exhaust 724. The gas exhaust 724 includes a vacuum pump. A conveying opening 725 is provided in a side surface of the processing vessel 702. The conveying opening 725 is openable and closable by a gate valve 726. The substrate W is loaded into or unloaded from the processing vessel 702 from or into a conveying chamber (not shown) via the conveying opening 725.

A mounting table 703 for holding the substrate W substantially horizontally is provided in the processing vessel 702. The mounting table 703 has a substantially circular shape in a plan view, and is supported by a support member 731. A substantially circular recess 732 is formed in the surface of the mounting table 703 to be mounted with a substrate W having a diameter of, for example, 300 mm. The recess 732 has an inner diameter slightly (for example, by approximately 1 mm to 4 mm) greater than the diameter of the substrate W. The depth of the recess 732 is, for example, substantially the same as the thickness of the substrate W. The mounting table 703 is composed of a ceramic material, such as aluminum nitride (AlN) and the like. The mounting table 703 may be composed of a metal material, such as nickel (Ni) and the like. Instead of the recess 732, a guide ring for guiding the substrate W may be provided on the periphery of the surface of the mounting table 703.

A lower electrode 733 is embedded in the mounting table 703. A temperature regulating mechanism 734 is embedded under the lower electrode 733. The temperature regulating mechanism 734 regulates the substrate W mounted on the mounting table 703 to a set temperature based on a control signal from a controller 709.

An RF power source 735 is connected to the lower electrode 733 via a matcher 735a. The RF power source 735 applies a power having a frequency (Low Frequency: LF) lower than the frequency of an RF power source 751 described later to the lower electrode 733. The low frequency power generated by the RF power source 735 is used as a bias low-frequency power for drawing ions into the substrate W. The frequency of the RF power source 735 is 450 kHz to 27 MHz, and is, for example, 13.56 MHz.

The mounting table 703 is provided with a plurality of (for example, 3) lifting pins 741 for raising and lowering the substrate W mounted on the mounting table 703 while holding the substrate W. The material of the lifting pins 741 may be, for example, ceramics, such as alumina (Al2O3) and the like, or may be quartz and the like. The lower ends of the lifting pins 741 are attached to a support plate 742. The support plate 742 is connected to a lifting mechanism 744 provided outside the processing vessel 702 via a lifting shaft 743.

The lifting mechanism 744 is provided, for example, under the gas exhaust chamber 721. A bellows 745 is provided between the lifting mechanism 744 and an opening 721a for the lifting shaft 743, formed in the lower surface of the gas exhaust chamber 721. The shape of the support plate 742 may be a shape that can be raised and lowered without interfering with the support member 731 of the mounting table 703. Lifting pins 741 are configured to be freely raised and lowered by the lifting mechanism 744 between the upper side of the surface of the mounting table 703 and the lower side of the surface of the mounting table 703. In other words, the lifting pins 741 are projectable from the upper surface of the mounting table 703.

The lower end of the support member 731 penetrates an opening 721b in the gas exhaust chamber 721 and is supported by a lifting mechanism 746 via a lifting plate 747 disposed under the processing vessel 702. A bellows 748 is provided between the bottom of the gas exhaust chamber 721 and the lifting plate 747, and the airtightness in the processing vessel 702 is maintained even against vertical movements of the lifting plate 747.

The mounting table 703 can be raised and lowered by the lifting mechanism 746 raising and lowering the lifting plate 747. Thus, the gap between the mounting table 703 and the lower surface of an upper electrode plate 705 can be adjusted.

The upper electrode plate 705 is provided in a top wall 727 of the processing vessel 702 via an insulating member 728. The upper electrode plate 705 constitutes an upper electrode, and is disposed in parallel with the lower electrode 733 to face the lower electrode 733. The RF power source 751 is connected to the upper electrode plate 705 via a matcher 751a. The RF power source 751 supplies a power having a frequency (High Frequency: HF) higher than the frequency of the RF power source 735 to the upper electrode plate 705. The high-frequency power generated by the RF power source 751 is used as a high-frequency power for formation of a plasma necessary for film formation on the substrate W. The frequency of the RF power source 751 is, for example, 450 KHz to 2.45 GHz. An RF power is applied from the RF power source 751 to the upper electrode plate 705. Thus, an RF electric field is generated between the mounting table 703 and the upper electrode plate 705. The upper electrode plate 705 includes a hollow gas diffusion chamber 752. A multitude of holes 753 for dispersively supplying the processing gas into the processing vessel 702 are arranged, for example, uniformly in the lower surface of the gas diffusion chamber 752. A heating mechanism 754 is embedded in the upper electrode plate 705, for example, above the gas diffusion chamber 752. The heating mechanism 754 is heated to a set temperature by being supplied with power from a power source (not shown) based on a control signal from the controller 709.

The gas diffusion chamber 752 is provided with a gas supply path 706. The gas supply path 706 communicates with the gas diffusion chamber 752. A gas source 761 is connected to the upstream side of the gas supply path 706 through a gas line 762. The gas source 761 includes, for example, supply sources of various processing gases, mass flow controllers, and valves (none of which are shown). The processing gas used in the method for forming the carbon-containing film includes a carbon-containing gas. The carbon-containing gas contains at least one of a gas containing carbon and hydrogen (CxHy), a gas containing carbon and fluorine (CxFy), a gas containing carbon and oxygen (for example, CO₂), and a gas containing carbon and metal (for example, an organometallic precursor, such as TDMAT and the like) (where x and y are desirable values). The carbon-containing gas contains, for example, CH₄, C₂H₂, C₂H₄, C₃H₆, and C₆H₆. The processing gas may also contain an inert gas or a dilution gas (for example, H₂, Ar, He, O₂, and N₂). The processing gas may also contain hydrogen gas. Various gases are introduced into the gas diffusion chamber 752 from the gas source 761 through the gas line 762.

The substrate processing apparatus 700 includes the controller 709. The controller 709 is, for example, a computer, and includes a Central Processing Unit (CPU), a Random Access Memory (RAM), a Read Only Memory (ROM), an auxiliary memory device, and the like. The CPU operates based on a program stored in the ROM or the auxiliary memory device, and controls the operation of the substrate processing apparatus 700. The controller 709 may be provided inside or outside the substrate processing apparatus 700. When the controller 709 is provided outside the substrate processing apparatus 700, the controller 709 can control the substrate processing apparatus 700 by wired, wireless, and other communication methods.

With this configuration, the substrate processing apparatus 700 forms a carbon-containing film on the surface of the substrate. Specifically, the controller 709 forms a carbon-containing film by a plasma of the carbon-containing gas. The substrate processing apparatus 700 also forms an H₂O plasma to hydrophilize the periphery of the substrate. The controller 709 controls the temperature regulating mechanism 734 to set the temperature of the substrate W to a predetermined temperature. The controller 709 controls the pressure regulator 723 and the gas exhaust 724 to set the pressure in the processing vessel 702 to a predetermined pressure. The controller 709 also controls the gas source 761 to supply the carbon-containing gas into the processing vessel 702. The controller 709 also controls the RF power source 751 to apply a high-frequency power (HF) to the upper electrode plate 705. The controller 709 controls the RF power source 735 to apply a low-frequency power (LF) to the lower electrode 733. Thus, a plasma of the carbon-containing gas is formed, and a carbon-containing film is formed on the substrate W by this plasma.

An example of the conditions for forming the DLC film 103 having a film stress of 1 GPa or greater is given below.

Processing pressure: 5 mT to 200 mT (0.67 Pa to 2.67 Pa)

Plasma power: 10 W to 2,000 W

Film thickness of the DLC film: 20 nm to 1 um

In the above description, an example in which a high-frequency power (HF) is applied to the upper electrode plate 705 and a low-frequency power (LF) is applied to the lower electrode 733 has been described. However, this is non-limiting. For example, two frequencies, namely, a high-frequency power (HF) and a low-frequency power (LF) may be applied to the upper electrode plate 705, and two frequencies, namely, a high-frequency power (HF) and a low-frequency power (LF), may be applied to the lower electrode 733.

In step S23 (FIG. 8), an H₂O plasma is formed under process conditions by which a plasma is formed only around the edge of the substrate, to hydrophilize the periphery of the substrate. When the second layer 102 is SiO or TiO, an H plasma may be formed under process conditions by which a plasma is formed only around the edge of the substrate, to hydrophilize the periphery of the substrate by the H plasma in step S23 (FIG. 8).

As described above, according to the substrate processing method and the substrate processing apparatus of the present embodiment, it is possible to selectively remove the carbon-containing film on the periphery of the substrate by controlling the state of the surface of the substrate.

The substrate processing method and the substrate processing apparatus according to the embodiments disclosed herein should be considered exemplary and not limiting in any respects. Modifications and improvements in various forms are applicable to the embodiments without departing from the scope of the appended claims and the spirit thereof. The matters described in the above embodiments may be configured in other ways to an extent that no contradiction occurs, and may be combined to an extent that no contradiction occurs.

The embodiments disclosed above have the following aspects, for example.

(Clause 1)

A substrate processing method, including:
preparing a substrate having a foundation film;
performing hydrophobization treatment in which a surface of the substrate is hydrophobized;
performing hydrophilization treatment in which a periphery of the substrate is selectively hydrophilized;
forming a carbon-containing film having a film stress of 1 GPa or greater on the substrate by setting a processing pressure to a first pressure; and
selectively removing the carbon-containing film on the hydrophilized periphery of the substrate by setting the processing pressure to a second pressure higher than the first pressure.

(Clause 2)

A substrate processing method, including:
preparing a substrate having a foundation film;
performing hydrophilization treatment in which a surface of the substrate is hydrophilized;
performing hydrophobization treatment in which, after a fixture is attached to cover a periphery of the substrate, the surface of the substrate not covered by the fixture is hydrophobized;
removing the fixture from the periphery of the substrate;
forming a carbon-containing film having a film stress of 1 GPa or greater on the substrate by setting a processing pressure to a first pressure; and
selectively removing the carbon-containing film on the periphery of the substrate that is hydrophilized, by setting the processing pressure to a second pressure higher than the first pressure.

(Clause 3)

The substrate processing method according to Clause 1 or 2,

wherein, in the hydrophobization treatment, the surface of the substrate is terminated with an Si-H group or an H group.

(Clause 4)

The substrate processing method according to Clause 3,

wherein the surface of the substrate contains Si, and

the hydrophobization treatment includes exposing the substrate to a first treatment solution.

(Clause 5)

The substrate processing method according to Clause 4,

wherein the first treatment solution contains at least one of DHF, BHF, TMSDMA, HMDS, or a silane coupling agent.

(Clause 6)

The substrate processing method according to Clause 4,

wherein the surface of the substrate is any one of Si, SiO₂, or SiN.

(Clause 7)

The substrate processing method according to Clause 3,

wherein the surface of the substrate is Si, TiN, SiO₂, SiN, a metal film, metal oxide, or metal nitride, and

the hydrophobization treatment includes exposing the substrate to a first processing gas.

(Clause 8)

The substrate processing method according to Clause 7,

wherein the first processing gas is an Si-containing gas containing an Si-H bond.

(Clause 9)

The substrate processing method according to Clause 8,

wherein the Si-containing gas containing the Si-H bond contains at least one of silane (SiH₄), disilane (Si₂H₆), trisilane (Si₃H₈), a higher-order silane, DCS (SiH₂Cl₂), trichlorosilane (SiHCl₃), or an organosilicon compound.

(Clause 10)

The substrate processing method according to Clause 7,

wherein the metal film, a metal contained in the metal oxide, and a metal contained in the metal nitride are any one of Ti, Ru, Mo, Mg, W, Co, Fe, or Cu.

(Clause 11)

The substrate processing method according to Clause 1 or 2,

wherein, in the hydrophilization treatment, the surface of the substrate is terminated with an OH group.

(Clause 12)

The substrate processing method according to Clause 4,

wherein the hydrophilization treatment includes selectively exposing the periphery of the substrate to a second treatment solution different from the first treatment solution.

(Clause 13)

The substrate processing method according to Clause 12,

wherein the second treatment solution contains at least one of ammonia-hydrogen peroxide, hydrochloric acid-hydrogen peroxide, ozone water (O₃), hydrogen peroxide (H₂O₂), sulfuric acid-hydrogen peroxide, or an ammonium peroxodisulfate aqueous solution.

(Clause 14)

The substrate processing method according to Clause 7,

wherein the hydrophilization treatment includes selectively exposing the periphery of the substrate to a plasma formed from a second processing gas different from the first processing gas.

(Clause 15)

The substrate processing method according to Clause 14,

wherein the second processing gas contains at least one of water (H₂O), hydrogen peroxide (H₂O₂), or ozone water (O₃).

(Clause 16)

The substrate processing method according to Clause 1 or 2,

wherein the forming of the carbon-containing film includes exposing the substrate to a plasma formed from a third processing gas containing a carbon-containing gas.

(Clause 17)

The substrate processing method according to Clause 16,

wherein the carbon-containing gas contains at least one of a gas containing carbon and hydrogen, a gas containing carbon and fluorine, a gas containing carbon and oxygen, or a gas containing carbon and metal.

(Clause 18)

The substrate processing method according to Clause 17,

wherein the carbon-containing gas is carbon-hydrogen gas.

(Clause 19)

The substrate processing method according to Clause 16,

wherein the third processing gas further contains an inert gas.

(Clause 20)

The substrate processing method according to Clause 19,

wherein the inert gas contains at least one of argon (Ar) gas, helium (He) gas, nitrogen (N₂) gas, xenon (Xe) gas, or krypton (Kr) gas.

(Clause 21)

The substrate processing method according to Clause 1 or 2,

wherein the first pressure is 0.13 Pa to 13.3 Pa.

(Clause 22)

The substrate processing method according to Clause 1 or 2, further including:
cleaning the substrate after the forming of the carbon-containing film.

(Clause 23)

The substrate processing method according to Clause 22,

wherein the cleaning of the substrate includes exposing the substrate to a third treatment solution.

(Clause 24)

The substrate processing method according to Clause 23,

wherein the third treatment solution contains pure water (De-Ionized Water: DIW).

(Clause 25)

The substrate processing method according to Clause 22,

wherein the cleaning of the substrate includes exposing the substrate to a fourth processing gas.

(Clause 26)

The substrate processing method according to Clause 25,

wherein the fourth processing gas contains N₂.

(Clause 27)

The substrate processing method according to Clause 22,

wherein the hydrophobization treatment, the hydrophilization treatment, the forming of the carbon-containing film, the selectively removing of the carbon-containing film, and the cleaning of the substrate are performed in a same processing vessel.

(Clause 28)

A substrate processing apparatus, including

a processing vessel;

a substrate support including a mounting surface configured to have a substrate mounted thereon;

a showerhead facing the substrate support and configured to supply a processing gas toward the substrate;

a gas supply source;

a plasma power source connected to the showerhead and configured to supply a plasma; and

a controller including a processor and a memory,

wherein the controller is configured to control:
preparing a substrate having a foundation film;
hydrophobizing a surface of the substrate;
selectively hydrophilizing a periphery of the substrate;
forming a carbon-containing film having a film stress of 1 GPa or greater on the substrate by setting a processing pressure to a first pressure;
selectively removing the carbon-containing film on the hydrophilized periphery of the substrate by setting the processing pressure to a second pressure higher than the first pressure; and
cleaning the substrate after the forming of the carbon-containing film, and
wherein the hydrophobizing, the hydrophilizing, the forming of the carbon-containing film, the selectively removing of the carbon-containing film, and the cleaning are performed in a same processing vessel.

According to one aspect, it is possible to selectively remove a carbon-containing film on the periphery of a substrate by controlling the state of a surface of the substrate.

What is claimed is:

1. A substrate processing method, comprising:
preparing a substrate having a foundation film;
performing hydrophobization treatment in which a surface of the substrate is hydrophobized;
performing hydrophilization treatment in which a periphery of the substrate is selectively hydrophilized;
forming a carbon-containing film having a film stress of 1 GPa or greater on the substrate by setting a processing pressure to a first pressure; and
selectively removing the carbon-containing film on the hydrophilized periphery of the substrate by setting the processing pressure to a second pressure higher than the first pressure.

2. The substrate processing method according to claim 1,
wherein, in the hydrophobization treatment, the surface of the substrate is terminated with an Si-H group or an H group, and
in the hydrophilization treatment, the surface of the substrate is terminated with an OH group.

3. The substrate processing method according to claim 1,
wherein the surface of the substrate is any one of Si, SiO₂ or SiN,
the hydrophobization treatment includes exposing the substrate to a first treatment solution, and
the first treatment solution contains at least one of DHF, BHF, TMSDMA, HMDS, or a silane coupling agent.

4. The substrate processing method according to claim 1,
wherein the surface of the substrate is Si, TiN, SiO₂ SiN, a metal film, metal oxide, or metal nitride,
the hydrophobization treatment includes exposing the substrate to a first processing gas,
the first processing gas is an Si-containing gas containing an Si-H bond, and
the Si-containing gas containing the Si-H bond contains at least one of silane (SiH₄), disilane (Si₂H₆), trisilane (Si₃H₈), a higher-order silane, DCS (SiH₂Cl₂), trichlorosilane (SiHCl₃), or an organosilicon compound.

5. The substrate processing method according to claim 3,
wherein the hydrophilization treatment includes selectively exposing the periphery of the substrate to a second treatment solution different from the first treatment solution, and
the second treatment solution contains at least one of ammonia-hydrogen peroxide, hydrochloric acid-hydrogen peroxide, ozone water (O₃), hydrogen peroxide (H₂O₂), sulfuric acid-hydrogen peroxide, or an ammonium peroxodisulfate aqueous solution.

6. The substrate processing method according to claim 4,
wherein the hydrophilization treatment includes selectively exposing the periphery of the substrate to a plasma formed from a second processing gas different from the first processing gas, and
the second processing gas contains at least one of water (H₂O), hydrogen peroxide (H₂O₂), or ozone water (O₃6).

7. The substrate processing method according to claim 1,
wherein the forming of the carbon-containing film includes exposing the substrate to a plasma formed from a third processing gas containing a carbon-containing gas, and
the carbon-containing gas contains at least one of a gas containing carbon and hydrogen, a gas containing carbon and fluorine, a gas containing carbon and oxygen, or a gas containing carbon and metal.

8. The substrate processing method according to claim 5, further comprising:
cleaning the substrate after the forming of the carbon-containing film,
wherein the cleaning of the substrate includes exposing the substrate to a third treatment solution, and
the third treatment solution contains pure water (De-Ionized Water: DIW).

9. The substrate processing method according to claim 6, further comprising:
cleaning the substrate after the forming of the carbon-containing film,
wherein the cleaning of the substrate includes exposing the substrate to a fourth processing gas, and
the fourth processing gas contains N₂.

10. The substrate processing method according to claim 6,
wherein the hydrophobization treatment, the hydrophilization treatment, the forming of the carbon-containing film, the selectively removing of the carbon-containing film, and the cleaning of the substrate are performed in a same processing vessel.

11. A substrate processing method, comprising:
preparing a substrate having a foundation film;
performing hydrophilization treatment in which a surface of the substrate is hydrophilized;
performing hydrophobization treatment in which, after a fixture is attached to cover a periphery of the substrate, the surface of the substrate not covered by the fixture is selectively hydrophobized;
removing the fixture from the periphery of the substrate;
forming a carbon-containing film having a film stress of 1 GPa or greater on the substrate by setting a processing pressure to a first pressure; and
selectively removing the carbon-containing film on the periphery of the substrate not hydrophobized, by setting the processing pressure to a second pressure higher than the first pressure.

12. The substrate processing method according to claim 11,
wherein, in the hydrophilization treatment, the surface of the substrate is terminated with an OH group, and
in the hydrophobization treatment, the surface of the substrate is terminated with an Si-H group or an H group.

13. The substrate processing method according to claim 11,
wherein the hydrophilization treatment includes exposing the substrate to a second treatment solution, and
the second treatment solution contains at least one of ammonia-hydrogen peroxide, hydrochloric acid-hydrogen peroxide, ozone water (O₃), hydrogen peroxide (H₂O₂), sulfuric acid-hydrogen peroxide, or an ammonium peroxodisulfate aqueous solution.

14. The substrate processing method according to claim 11,
wherein the hydrophilization treatment includes exposing the substrate to a plasma formed from a second processing gas, and
the second processing gas contains at least one of water (H₂O), hydrogen peroxide (H₂O₂), or ozone water (O₃14).

15. The substrate processing method according to claim 11,
wherein the surface of the substrate is any one of Si, SiO₂ or SiN,
the hydrophobization treatment includes exposing the substrate to a first treatment solution, and
the first treatment solution contains at least one of DHF, BHF, TMSDMA, HMDS, or a silane coupling agent.

16. The substrate processing method according to claim 11,
wherein the surface of the substrate is Si, TiN, SiO₂ SiN, a metal film, metal oxide, or metal nitride,
the hydrophobization treatment includes exposing the substrate to a first processing gas,
the first processing gas is an Si-containing gas containing an Si-H bond, and
the Si-containing gas containing the Si-H bond contains at least one of silane (SiH₄), disilane (Si₂H₆), trisilane (Si₃H₈), a higher-order silane, DCS (SiH₂Cl₂), trichlorosilane (SiHCl₃), or an organosilicon compound.

17. The substrate processing method according to claim 11,
wherein the forming of the carbon-containing film includes exposing the substrate to a plasma formed from a third processing gas containing a carbon-containing gas, and
the carbon-containing gas contains at least one of a gas containing carbon and hydrogen, a gas containing carbon and fluorine, a gas containing carbon and oxygen, or a gas containing carbon and metal.

18. The substrate processing method according to claim 13, further comprising:
cleaning the substrate after the forming of the carbon-containing film,
wherein the cleaning of the substrate includes exposing the substrate to a third treatment solution, and
the third treatment solution contains pure water (De-Ionized Water: DIW).

19. The substrate processing method according to claim 14, further comprising:
cleaning the substrate after the forming of the carbon-containing film,
wherein the cleaning of the substrate includes exposing the substrate to a fourth processing gas, and
the fourth processing gas contains N₂.

20. A substrate processing apparatus, comprising:
a processing vessel;
a substrate support including a mounting surface configured to have a substrate mounted thereon;
an upper electrode plate facing the substrate support and configured to supply a processing gas toward the substrate;
a gas supply source;
a plasma power source connected to the upper electrode plate and configured to supply a plasma; and
a controller including a processor and a memory,
wherein the controller is configured to control:
preparing a substrate having a foundation film;
hydrophobizing a surface of the substrate;
selectively hydrophilizing a periphery of the substrate;
forming a carbon-containing film having a film stress of 1 GPa or greater on the substrate by setting a processing pressure to a first pressure;
selectively removing the carbon-containing film on the hydrophilized periphery of the substrate by setting the processing pressure to a second pressure higher than the first pressure; and
cleaning the substrate after the forming of the carbon-containing film, and
wherein the hydrophobizing, the hydrophilizing, the forming of the carbon-containing film, the selectively removing of the carbon-containing film, and the cleaning are performed in a same processing vessel.
